(19) United States
(12) Patent Application Publication
(10) Pub. No.: US 2017/0348806 A1
(43) Pub. Date: Dec. 7, 2017

(54) SOLDER PASTE

(71) Applicant: SUMITOMO METAL MINING CO., LTD., Tokyo (JP)

(72) Inventor: Masato TAKAMORI, Tokyo (JP)

(21) Appl. No.: 15/684,072

(22) Filed: Aug. 23, 2017

Related U.S. Application Data
(63) Continuation of application No. PCT/JP2016/052335, filed on Jan. 27, 2016.

(30) Foreign Application Priority Data
Mar. 31, 2015 (JP) 2015-071978

(51) Int. Cl. B23K 35/26; B23K 35/02; C22C 12/00

(52) U.S. Cl. CPC B23K 35/262; B23K 35/264; C22C 12/00; B23K 35/025; H01L 2224/29111; H01L 2924/01047; H01L 2224/27332

(57) ABSTRACT

A solder paste including metal powders, constituted by an alloy powder including bismuth and silver, and a tin powder, the alloy powder including bismuth and silver including silver at a ratio of greater than or equal to 0.1 wt % and less than or equal to 11.0 wt % is provided.

### CROSS-REFERENCE TO RELATED APPLICATION

This application is a continuation application filed under 35 U.S.C. 111(a) claiming the benefit under 35 U.S.C. 120 and 365(c) of PCT International Application No. PCT/JP2016/052335 filed on Jan. 27, 2016, which is based upon and claims the benefit of priority of Japanese Priority Application No. 2015-071978 filed on Mar. 31, 2015 and the entire contents of which are hereby incorporated by reference.

### BACKGROUND OF THE INVENTION

### 1. Field of the Invention

The present invention relates to a solder paste.

### 2. Description of the Related Art

It is particularly required for solder pastes used for fabricating various electronic components, semiconductor devices and the like to satisfy the following (1) to (3) and the like, among characteristics required for normal solder pastes such as wettability or the like to a member to be bonded.
(1) Soldering is possible at temperature of less than or equal to 320° C.
(2) A soldered component is not re-melted at a temperature of 200° C., which is the maximum operating temperature, after being mounted on a printed circuit board.
(3) Reliability of a solder bonding portion can be retained, in other words, the solder bonding portion is not deteriorated under a service environment of relatively high temperature.

As a solder paste that has these characteristics, a high melting point solder paste including Pb-5 wt % Sn is conventionally used, for example. However, recently, a solder paste that does not include lead, a so-called lead-free high melting point solder paste is required in a viewpoint of preventing environmental pollution. As a lead-free high melting point solder paste, an appropriate material that satisfies all of the above described (1) to (3) is not found, and various investigations are performed.

For example, Patent Document 1 discloses a solder paste including approximately 60 wt % to approximately 92 wt % of a first solder alloy powder, greater than 0 wt % and less than or equal to approximately 12 wt % of a second solder alloy powder and flux, wherein the first solder alloy powder includes a first solder alloy having solid phase temperature that exceeds approximately 260° C., and the second solder alloy powder includes a second solder alloy having solid phase temperature that is less than approximately 250° C. Then, it is also disclosed that the first solder alloy includes Bi—Ag, Bi—Cu or Bi—Ag—Cu alloy.

### Patent Document

Patent Document 1: Japanese Laid-open Patent Publication (Translation of PCT Application) No. 2013-525121

### SUMMARY OF THE INVENTION

An aspect of the present invention is made in light of the above problems, and provides a solder paste capable of forming a solder bonding portion with a sufficient bonding strength.

According to an aspect of the invention, there is provided a solder paste including metal powders, constituted by an alloy powder including bismuth and silver, and a tin powder, the alloy powder including bismuth and silver including silver at a ratio of greater than or equal to 0.1 wt % and less than or equal to 11.0 wt %.

According to an aspect of the invention, a solder paste is provided capable of forming a solder bonding portion with a sufficient bonding strength.

### BRIEF DESCRIPTION OF THE DRAWINGS

FIG. 1 is a view for describing a structure of a test piece manufactured in each example and comparative example.

### DETAILED DESCRIPTION OF THE PREFERRED EMBODIMENTS

Hereinafter, an embodiment of a solder paste is described.

The solder paste of the embodiment may include metal powders, wherein the metal powders may be constituted by an alloy powder including bismuth and silver, and a tin powder. Further, the alloy powder including bismuth and silver may include silver at a ratio of greater than or equal to 0.1 wt % and less than or equal to 11.0 wt %.

Here, there is a case that a pad including an Au layer as an outermost layer and a Ni layer as an under layer is used as a member to be bonded.

However, when the solder paste using the alloy including Bi as disclosed in Patent Document 1 is applied for bonding with such a pad, Ni in the under layer may diffuse into the solder to form a fragile bismuth-nickel (Bi—Ni) alloy in a solder bonding portion. Further, as the volume shrinks when the bismuth-nickel alloy is formed, a space may be generated between a layer of the bismuth-nickel alloy and an adjacent layer. From these reasons, there is a problem that a bonding strength of the solder bonding portion may be lowered and reliability may not be ensured.

The present inventors investigated a method capable of forming a solder bonding portion with a sufficient bonding strength when a solder paste using an alloy including bismuth is applied to bonding with a pad including an Au (gold) layer as an outermost layer and a Ni (nickel) layer as an under layer (ground layer). Then, the present inventors found that formation of a bismuth-nickel alloy could be suppressed and a solder bonding portion with a sufficient bonding strength could be formed when metal powders included in the solder paste are constituted by an alloy powder including bismuth and silver and a tin powder and completed the present invention.

First, metal powders included in the solder paste of the embodiment are described.

The metal powders may be constituted by an alloy powder including bismuth and silver and a tin powder. In other words, the metal powders may be mixed powders of the alloy powder including bismuth and silver and the tin powder.

The alloy powder including bismuth and silver is described.

Bismuth included in the alloy powder including bismuth and silver may be added as a main component of the solder paste of the embodiment. Here, the main component means a component that is included in the solder paste most by a mass ratio.

As a melting point of bismuth is 271° C., by including bismuth, a solder paste that is not re-melted at temperature of approximately 200° C. and capable of soldering at temperature of less than or equal to 320° C., which are required for the high melting point lead-free solder paste, can be relatively easily obtained.

As it is fragile if only bismuth is included, silver is added to form the alloy powder including bismuth and silver. By forming such a powder of an alloy including bismuth and silver, relaxation of stress can be improved. It is preferable that the content of silver in the alloy powder including bismuth and silver may be greater than or equal to 0.1 wt %, and more preferably, greater than or equal to 1.0 wt %.

This is because if the content of silver included in the alloy powder including bismuth and silver is greater than or equal to 0.1 wt %, the relaxation of stress of the alloy including bismuth and silver can be improved.

It is preferable that an upper limit value of the content of silver included in the alloy powder including bismuth and silver is less than or equal to 11.0 wt %, and more preferably, less than or equal to 5.0 wt %. This is because if the content of silver of the alloy powder including bismuth and silver exceeds 11.0 wt %, a melting point of the alloy including bismuth and silver may exceed 320° C., and in such a case, the member to be bonded such as a substrate may be damaged by heat when heating the solder paste to be melted.

The alloy powder including bismuth and silver may further include an optionally selectable component other than bismuth and silver. For example, the alloy powder including bismuth and silver may further include one or more types of metals selected from Cu, Zn, Al, Ni, Ge, P and the like. However, as the solder paste of the embodiment is a lead-free solder paste, it is preferable that the alloy powder including bismuth and silver does not include lead (Pb) except as an inevitable component. The alloy powder including bismuth and silver may be constituted only by bismuth and silver. In other words, the alloy powder including bismuth and silver may be a bismuth-silver alloy powder.

Next, the tin powder is described.

According to the investigation by the present inventors, when the metal powders include tin powder in addition to the alloy powder including bismuth and silver, by a reaction of gold of the Au layer included in the pad and tin, an AuSn layer which is a layer of an alloy of gold and tin can be formed between a surface of the pad and the solder bonding portion. The formed AuSn layer can function as a barrier layer and can prevent nickel of the Ni layer, which is the under layer, from diffusing into the solder bonding portion to suppress formation of the bismuth-nickel alloy. Thus, the solder bonding portion with a sufficient bonding strength can be formed, and reliability of the solder bonding portion can be retained.

The tin powder may be constituted by a metal-tin simple substance. In other words, the tin powder may consist of metal-tin. This is because by using the tin powder constituted by the metal-tin simple substance, a compact AuSn layer can be formed and diffusion of nickel can be suppressed.

Further, if tin is added as an alloy component of the alloy powder including bismuth and silver, or alternatively, tin is added as a powder of an alloy including tin, not as the powder of the metal-tin simple substance, the alloy powder including tin does not melt until temperature becomes a melting point of the alloy. On the other hand, according to the solder paste of the embodiment, by adding the tin powder constituted by the metal-tin simple substance, the tin powder can melt at a melting point of tin, and can melt at relatively low temperature. Thus, gold of the Au layer included in the pad and tin can react at temperature near the melting point of tin to form the AuSn layer, and nickel of the Ni layer, which is the under layer, can be surely prevented from being diffused into the solder bonding portion, and formation of the bismuth-nickel alloy can be suppressed.

Further, as will be described later, an addition amount of the tin powder may be selectable in accordance with a thickness of the Au layer or the like. Thus, by adding the tin powder separately from the alloy powder including bismuth and silver, not by adding tin in the alloy powder including bismuth and silver to be included as an alloy, a solder paste having an optimum composition in accordance with a structure of a pad, which is a member to be bonded, can be easily provided.

A percentage of the tin powder in the metal powders is not specifically limited, and for example, may be selectable in accordance with an amount of the solder paste used for bonding, a thickness of the Au layer of the pad included in the member to be bonded or the like. For example, it is preferable that the percentage of the tin powder in the metal powders is greater than or equal to 3.0 wt % and less than or equal to 30.0 wt %, and more preferably, greater than or equal to 5.0 wt % and less than or equal to 20.0 wt %.

This is because when the percentage of the tin powder in the metal powders is greater than or equal to 3.0 wt %, the AuSn layer with a sufficient thickness can be formed and formation of the bismuth-nickel alloy can be furthermore surely suppressed. However, when the percentage of the tin powder in the metal powders exceeds 30.0 wt %, excess tin remains in the solder ponding portion with a relatively large amount. Then, as a melting point of tin is low, particularly, for a use of bonding a member to be bonded or the like that becomes high temperature when being used or the like, a part of the solder bonding portion is melted and the solder bonding portion becomes fragile due to generation of a void or the like. Thus, reliability of the solder bonding portion may be lowered. Therefore, it is preferable that the percentage of the tin powder in the metal powders is less than or equal to 30.0 wt %.

A particle diameter of each of the bismuth-silver alloy powder and the tin powder constituting the metal powders is not particularly limited. For example, the particle diameter of each of the bismuth-silver alloy powder and the tin powder constituting the metal powders may be selectable in accordance with a degree of dispersion when being formed into a solder paste, workability when coating on the pad or the like.

Here, although it is described that the metal powders are constituted by the alloy powder including bismuth and silver and the tin powder, as described above, this does not mean to exclude a case where inevitable components such as impurities are included.

The solder paste of the embodiment may include an optionally selectable component in addition to the above described metal powders. For example, the solder paste include flux for forming a paste by being mixed with the metal powders.

The flux is not specifically limited, and may be selectable in accordance with purposes or the like such as resin-based, organic acid based, inorganic acid based or the like, for example. For example, flux including rosin or resin, a solvent, an activator, a thixotropic agent and the like may be used.

As the rosin, rosin, a rosin derivative or the like may be used, and as the solvent, ethylene glycol monobutyl ether, ethylene glycol monophenyl ether or the like may be used. Further, as the activator, diphenylguanidine HBr, diethylamine HCl or the like may be used, and as the thixotropic agent, hydrogenated castor oil, fatty acid amide or the like may be used.

A mixing ratio of the metal powders and the flux is not specifically limited as well, and may be selectable in accordance with flowability or the like required for the solder paste. For example, it is preferable that a percentage of the flux in a mixture of the metal powders and the flux is greater than or equal to 3.0 wt % and less than or equal to 15.0 wt %, and more preferably, greater than or equal to 5.0 wt % and less than or equal to 12.0 wt %.

The solder paste of the embodiment is described so far. As described above, the solder paste of the embodiment is particularly preferably used for bonding a pad including an Au layer as an outermost layer and a Ni layer as an under layer and another member to be bonded. However, the solder paste of the embodiment is not limited to be used for such a purpose, and for example, may be used for various purposes in which a high melting point lead-free solder paste is required.

A bonding strength of a solder bonding portion formed by using the solder paste of the embodiment is not specifically limited because it is different based on materials of members to be bonded, a purpose to be used or the like. However, it is preferable that a bonding strength (initial bonding strength) of a structural body of two members bonded by the solder paste of the embodiment immediately after bonding is greater than or equal to 20.0 MPa, and more preferably, greater than or equal to 30.0 MPa. A bonding strength of a structural body may be measured by a shear test at room temperature.

Further, it is preferable that a bonding strength of the structural body of the two members by the solder paste of the embodiment after heating the structural body at 200° C. for 100 hours or 200 hours is greater than or equal to 20.0 MPa as well, and more preferably, greater than or equal to 30.0 MPa. Here, the above described heating period at 200° C. may include a temperature rising period from room temperature.

According to the solder paste of the embodiment as described above, a solder bonding portion with a sufficient bonding strength can be formed when used for bonding with a pad including an Au layer as an outermost layer and a Ni layer as an under layer.

### EXAMPLES

Although specific examples and comparative examples are described below, the present invention is not limited to such examples.

First, methods of evaluating a solder paste manufactured in each of the following examples and comparative examples are described.

### (Bonding Test, Evaluation of Bonding Interface)

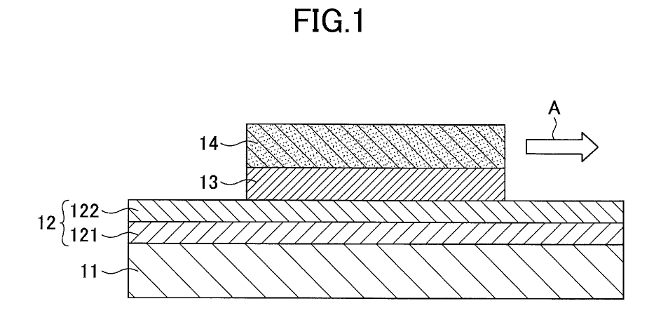

First, a test piece as illustrated in FIG. 1 was manufactured. FIG. 1 schematically illustrates a cross-sectional view at a plane that is in parallel to a stacking direction of layers constituting the test piece.

As illustrated in FIG. 1, one of members to be bonded was prepared, in which a pad 12 including a Ni layer 121 as an under layer and an Au layer 122 as an outermost layer was formed on a base 11 made of a Kovar material of 20 mm×20 mm. Here, the Ni layer 121 and the Au layer 122 were deposited by plating such that the Ni layer 121 became 20 mm×20 mm with a thickness of 5 μm, and the Au layer 122 became 20 mm×20 mm with a thickness of 3 μm.

Then, a solder paste manufactured in each of the examples and comparative examples was printed on the pad 12 to be 3 mm×3 mm with a thickness of 50 μm to 60 μm, and a solder bonding portion 13 was formed. A silicon chip 14 of 3 mm×3 mm with a thickness of 0.30 mm was mounted on the solder bonding portion 13 as the other of the members to be bonded.

The prepared structural body was placed in a heating furnace, retained for 3 minutes after rising temperature from room temperature to 320° C. at a rising temperature speed of 4° C./sec. under air atmosphere, and cooled to room temperature thereafter to manufacture a test piece. Here, in order to perform tests described below in which the test piece was retained at 200° C., four test pieces were manufactured for each of the examples and comparative examples by the same condition.

Whether the one of the members to be bonded and the other of the members to be bonded were bonded was simply confirmed as a bonding test, for one of the test pieces manufactured in each of the examples and comparative examples. As the silicon chip 14, which was the other of the members to be bonded, was placed on the one of the members to be bonded, force was applied to the other of the members to be bonded by a hand in a horizontal direction, and if the other of the members to be bonded was separated from the one of the members to be bonded, it was determined that they could not be bonded and evaluated to be “x” (bad). If the other of the members to be bonded and the one of the members to be bonded were not separated, it was determined that they could be bonded and evaluated to be “o” (good).

Further, as evaluation of a bonding interface, qualitative analysis was performed for an interface of the solder bonding portion 13 of the test piece between the pad 12 by SEM S-4800 (HITACHI) and EDX GENESIS 2000 (EDAX). Then, it was confirmed whether nickel of the Ni layer 121 and bismuth reacted with each other and a bismuth-nickel alloy was generated at the interface of the solder bonding portion 13 with the pad 12. If generation of the bismuth-nickel alloy was not observed, it was evaluated to be “0” (good), if the bismuth-nickel alloy was observed at the bonding interface by an area greater than or equal to 10.0% and less than 30.0%, it was evaluated to be “Δ” (middle), and if the bismuth-nickel alloy was observed at the bonding interface by an area greater than or equal to 30.0%, it was evaluated to be “x” (bad).

### (Shear Test)

A shear test was performed for the test piece having the structure illustrated in FIG. 1, manufactured in each of the examples and comparative examples, under air atmosphere, at room temperature after heating it at 200° C. for a predetermined period to evaluate the bonding strength. The evaluation was performed after retaining the test piece at 200° C. for 100 hours, and for 200 hours, respectively. Further, for comparison, a shear test for evaluating an initial bonding strength of a sample before being heated at 200° C. was also performed. Here, as described above, the above described retaining period includes a temperature rising period, as will be described later.

As the shear test is a breaking test, the initial bonding strength, a bonding strength after being retained for 100 hours, and a bonding strength after being retained for 200 hours were measured for three test pieces among the test pieces manufactured for each of the examples and comparative examples.

The shear test was performed, for the test piece having the structure illustrated in FIG. 1, by fixing the one of the members to be bonded at the base 11, and applying force to the silicon chip 14 in a direction of a block arrow “A” illustrated in FIG. 1. Then, a strength at which the test piece was broken was determined to be the bonding strength of the test piece.

Further, as the condition of heating the test piece to 200° C., the temperature was risen from room temperature at 1° C./minute, and retained at 200° C. after reaching 200° C. Then, when 100 hours had passed or when 200 hours had passed after starting temperature rising, the test piece was taken out from the heating furnace, and the shear test was preformed after the test piece was cooled to room temperature.

Next, manufacturing steps of the solder paste of each of the examples and comparative examples are described.

### Example 1

Metal powders were prepared in which a bismuth-silver alloy powder (mean particle diameter 30 μm) including 0.5 wt % of silver and 99.5 wt % of bismuth, and a tin powder (mean particle diameter 30 μm) were mixed.

Here, they were mixed such that the content of the tin powder in the metal powders was 5 wt % and the content of the bismuth-silver alloy powder in the metal powders was 95 wt %.

Hereinafter, a composition of such metal powders is described as Bi/0.5Ag+5Sn.

A solder paste was formed by mixing the above described metal powders with flux.

As the flux, a rosin main component, a non-halogen type was used. An addition amount of the flux was adjusted so that viscosity of a mixture of the metal powders and the flux became 190 Pa·S and a solder paste was formed by mixing them. The viscosity here means viscosity measured by a viscometer (manufactured by Malcom Co., Ltd., model type: PCU-203) at a rotating condition of 10 rpm at 25° C.

By similarly adjusting an addition amount of flux when preparing a solder paste in each of the following examples and comparative examples, the content of the flux in the respective solder paste was within a range of 7.0 wt % to 11.0 wt %.

The above described bonding test, the evaluation of the bonding interface and the shear test were performed for each of the obtained solder pastes. Results are illustrated in Table 1.

### Example 2 to Example 11

In each example, a solder paste was manufactured similarly as example 1 except that metal powders having a composition illustrated in Table 1 were used.

For the metal powders illustrated in example 2, the bismuth-silver alloy powder included 0.5 wt % of silver, and remnant, in other words, 99.5 wt % was constituted by bismuth. The metal powders included 10 wt % of a tin powder and 90 wt % of a bismuth-silver alloy powder.

Further, for the metal powders illustrated in example 11, the alloy powder including bismuth and silver included copper, nickel and germanium in addition to bismuth and silver. Such an alloy powder including bismuth and silver includes 3 wt % of silver, 0.1 wt % of copper, 0.1 wt % of nickel, 0.05 wt % of germanium and 96.75 wt % of bismuth. The metal powders include 90 wt % of such an alloy powder including bismuth and silver and 10 wt % of the tin powder.

In each of the examples, the obtained solder paste was evaluated similarly as example 1. Results are illustrated in Table 1.

### Comparative Example 1 to Comparative Example 3

A solder paste was manufactured similarly as example 1 except that metal powders having a composition illustrated in Table 1 were used.

The obtained solder paste was evaluated similarly as example 1. Results are illustrated in Table 1.

### Comparative Example 4

As illustrated in Table 1, a solder paste was manufactured similarly as example 1 except that metal powders in which a bismuth-silver alloy powder (mean particle diameter 30 μm) including 2.6 wt % of silver, and a tin-zinc alloy powder were mixed were used.

Here, as illustrated in Table 1, the bismuth-silver alloy powder included in the metal powders including 2.6 wt % of silver, and remnant, in other words 97.4 wt % was constituted by bismuth.

Further, as illustrated in Table 1, the tin-zinc alloy powder included 1.8 wt % of zinc, and remnant, in other words, 98.2 wt % was tin.

Further, the metal powders included 20 wt % of the tin-zinc alloy powder, and remnant, in other words, 80 wt % was the bismuth-silver alloy powder.

The obtained solder paste was evaluated similarly as example 1. Results are illustrated in Table 1.

### Comparative example 5

As illustrated in Table 1, a solder paste was manufactured similarly as example 1 except that metal powders in which a bismuth-silver alloy powder (mean particle diameter 30 μm) including 2.6 wt % of silver, and a tin-silver-copper alloy powder were mixed were used.

As illustrated in Table 1, the bismuth-silver alloy powder included in the metal powders included 2.6 wt % of silver, and remnant, 97.4 wt % was constituted by bismuth.

Further, as illustrated in Table 1, the tin-silver-copper alloy powder included 0.06 wt % of silver and 0.01 wt % of copper, and remnant, in other words, 99.93 wt % was tin.

Then, the metal powders included 1.9 wt % of the tin-silver-copper alloy powder, and remnant, in other words, 98.1 wt % was a bismuth-silver alloy powder.

The obtained solder paste was evaluated similarly as example 1. Results are illustrated in Table 1.

TABLE 1

| | | | EVALUATION | | | |
|---|---|---|---|---|---|---|
| | COMPOSITION | | OF | SHEAR TEST (Mpa) | | |
| | OF METAL | BONDING | BONDING | INITIAL | 100 | 200 |
| | POWDERS | TEST | INTERFACE | BONDING | HOURS | HOURS |
| EXAMPLE 1 | Bi/0.5Ag + 5Sn | ◯ | ◯ | 37.0 | 34.9 | 36.0 |
| EXAMPLE 2 | Bi/0.5Ag + 10Sn | ◯ | ◯ | 38.1 | 36.0 | 37.0 |
| EXAMPLE 3 | Bi/0.5Ag + 15Sn | ◯ | ◯ | 37.0 | 33.8 | 33.8 |
| EXAMPLE 4 | Bi/3Ag + 2Sn | ◯ | Δ | 22.0 | 21.0 | 20.2 |
| EXAMPLE 5 | Bi/3Ag + 5Sn | ◯ | ◯ | 37.0 | 34.9 | 32.7 |
| EXAMPLE 6 | Bi/3Ag + 10Sn | ◯ | ◯ | 34.9 | 32.7 | 31.6 |
| EXAMPLE 7 | Bi/3Ag + 30Sn | ◯ | ◯ | 34.9 | 32.7 | 31.6 |
| EXAMPLE 8 | Bi/3Ag + 35Sn | ◯ | ◯ | 23.0 | 22.0 | 20.0 |
| EXAMPLE 9 | Bi/11Ag + 5Sn | ◯ | ◯ | 37.0 | 36.0 | 37.0 |
| EXAMPLE 10 | Bi/11Ag + 10Sn | ◯ | ◯ | 37.0 | 31.6 | 33.8 |
| EXAMPLE 11 | Bi/3Ag/0.1Cu/ | ◯ | ◯ | 38.0 | 37.0 | 35.0 |
| | 0.1Ni/0.05Ge + | | | | | |
| | 10Sn | | | | | |
| COMPARATIVE | Bi/0.05Ag + 2Sn | ◯ | X | 15.0 | 13.1 | 12.0 |
| EXAMPLE 1 | | | | | | |
| COMPARATIVE | Bi/0.05Ag + 5Sn | ◯ | ◯ | 15.0 | 14.0 | 14.2 |
| EXAMPLE 2 | | | | | | |
| COMPARATIVE | Bi/12Ag + 5Sn | X | — | — | — | — |
| EXAMPLE 3 | | | | | | |
| COMPARATIVE | Bi/2.6Ag + 20Sn/ | ◯ | X | 14.0 | 11.0 | 11.2 |
| EXAMPLE 4 | 1.8Zn | | | | | |
| COMPARATIVE | Bi/2.6Ag + 1.9Sn/ | ◯ | X | 19.5 | 13.1 | 10.9 |
| EXAMPLE 5 | 0.06Ag/0.01Cu | | | | | |

According to results of the bonding test in Table 1, the metal powders included in the solder paste were melted at 320° C., and it was confirmed that the one of the members to be bonded in which the pad 12 was formed on the base 11 and the other of the members to be bonded, which was the silicon chip 14, could be bonded, in each of example 1 to example 11.

On the other hand, in comparative example 3, as the content of silver in the bismuth-silver alloy powder was large, and the melting point became high, a part of the metal powders in the solder paste was not melted, and it was confirmed that the one of the members to be bonded and the other of the members to be bonded could not be bonded. Here, in Table 1, it is described as “−” for the evaluation of the bonding interface and the shear test in comparative example 3. This means that as the two members to be bonded could not be bonded, the evaluation of the bonding interface and the shear test were not performed.

Further, in all of each of example 1 to example 11, the initial bonding strength was greater than or equal to 20 MPa, and it was confirmed that the two members to be bonded could be bonded with a sufficient strength. It can be considered that this is because an AuSn layer was formed at a surface of the pad, when bonding the two members to be bonded, and generation of the bismuth-nickel alloy in the solder bonding portion could be suppressed.

However, the initial bonding strengths were 22.0 MPa and 23.0 MPa in example 4 and example 8, respectively, and although sufficient initial bonding strengths could be obtained, it was confirmed that the initial bonding strength became small, compared with other examples such as example 1.

For example 4, as the content of the tin powder in the metal powders was small, the AuSn layer was not sufficiently formed at a part, and a reaction between bismuth and nickel occurred, even though it is a very small amount. Thus, the evaluation of bonding interface was “Δ”. It can be considered that the fragile bismuth-nickel alloy was partially formed, and the initial bonding strength of the solder bonding portion became small compared with other examples.

Further, for example 8, as the content of the tin powder in the metal powders was large, it can be considered that excessive tin that did not react with gold of the Au layer remains in the solder bonding portion with a relatively large amount. Thus, it can be considered that the initial bonding strength or the bonding strength after heated at 200° C. of the solder bonding portion became small compared with other examples.

On the other hand, according to comparative examples 1 and 2, as the content of silver included in the bismuth-silver alloy powder was small, the bonding strength of the solder bonding portion could not be sufficiently increased, and it was confirmed that the initial bonding strength was 15.0 MPa, which was smaller compared with those of example 1 to example 11.

Further, in each of comparative example 4 and comparative example 5, it was confirmed that the evaluation of bonding interface was “x” (bad). According to this bonding test, it was confirmed that, when adding tin to the metal powders, it is preferable to add as a tin powder, not as a powder of a tin alloy.

Although a preferred embodiment of the solder paste has been specifically illustrated and described, it is to be understood that minor modifications may be made therein without departing from the spirit and scope of the invention as defined by the claims.

What is claimed is:

1. A solder paste comprising:
metal powders including
an alloy powder including bismuth and silver, the alloy powder including silver at a ratio of greater than or equal to 0.1 wt % and less than or equal to 11.0 wt %, and
a tin powder.

2. The solder paste according to claim 1, wherein the alloy powder including bismuth and silver is a bismuth-silver alloy powder constituted by bismuth and silver.

3. The solder paste according to claim 1, wherein a ratio of the tin powder with respect to the metal powders is greater than or equal to 3.0 wt % and less than or equal to 30.0 wt %.

4. The solder paste according to claim 3, wherein the alloy powder including bismuth and silver is a bismuth-silver alloy powder constituted by bismuth and silver.

5. The solder paste according to claim 1, wherein the solder paste is used for bonding a pad including an Au layer as an outermost layer and a Ni layer as an under layer, with another member to be bonded.

6. The solder paste according to claim 1, wherein the tin powder consist of metal-tin.

7. The solder paste according to claim 1, wherein the alloy powder including bismuth and silver consist of bismuth and silver.

8. The solder paste according to claim 1, wherein the metal powders include bismuth as a main component.
